(19) United States
(12) Patent Application Publication
(10) Pub. No.: US 2025/0075103 A1
(43) Pub. Date: Mar. 6, 2025

(54) SLURRY SOLUTION, METHOD FOR FABRICATING THE SLURRY SOLUTION, AND METHOD FOR FABRICATING SEMICONDUCTOR DEVICE USING THE SLURRY SOLUTION

(71) Applicant: SAMSUNG ELECTRONICS CO., LTD., Suwon-si (KR)

(72) Inventors: In Hyeong LEE, Suwon-si (KR); Dong Hoon Kwon, Suwon-si (KR)

(73) Assignee: SAMSUNG ELECTRONICS CO., LTD., Suwon-si (KR)

(21) Appl. No.: 18/640,617

(22) Filed: Apr. 19, 2024

(30) Foreign Application Priority Data
Sep. 6, 2023 (KR) 10-2023-0118114

(51) Int. Cl. C09G 1/02; H01L 21/02

(52) U.S. Cl. CPC C09G 1/02; H01L 21/02024

(57) ABSTRACT

A slurry solution includes an abrasive including a first frame portion including an oxide and having a spherical shape, a plurality of pores in the abrasive, and a plurality of first abrasive elements at least partially filling the plurality of pores, where the plurality of first abrasive elements include Ce(OH)₄.

### CROSS-REFERENCE TO RELATED APPLICATION

This application is based on and claims priority to Korean Patent Application No. 10-2023-0118114, filed on Sep. 6, 2023, in the Korean Intellectual Property Office, the disclosure of which is incorporated herein by reference in its entirety.

### BACKGROUND

### 1. Field

Example embodiments of the disclosure relate to a slurry solution, a method of fabricating a slurry solution, and a method of fabricating a semiconductor device using a slurry solution.

### 2. Description of Related Art

A general chemical mechanical polishing (CMP) process may be a process in which a surface of a wafer is polished using abrasive elements. Recently, as a generation of a semiconductor device increases, a polishing amount required in the CMP process is increasing.

Information disclosed in this Background section has already been known to or derived by the inventors before or during the process of achieving the embodiments of the present application, or is technical information acquired in the process of achieving the embodiments. Therefore, it may contain information that does not form the prior art that is already known to the public.

### SUMMARY

One or more example embodiments provide a slurry solution that increases a surface region of abrasive elements contained in an abrasive, increasing the productivity of the chemical mechanical polishing (CMP) process and reducing the cost of the CMP process.

One or more example embodiments provide a method for fabricating a slurry solution that increases a surface region of abrasive elements contained in an abrasive, increasing the productivity of the CMP process and reducing the cost of the CMP process.

One or more example embodiments provide a method for fabricating a semiconductor device using a slurry solution that increases a surface region of abrasive elements contained in an abrasive, increasing the productivity of the CMP process and reducing the cost of the CMP process.

Additional aspects will be set forth in part in the description which follows and, in part, will be apparent from the description, or may be learned by practice of the presented embodiments.

According to an aspect of an example embodiment, a slurry solution may include an abrasive including a first frame portion including an oxide and having a spherical shape, a plurality of pores in the abrasive, and a plurality of first abrasive elements at least partially filling the plurality of pores, where the plurality of first abrasive elements include Ce(OH)₄.

According to an aspect of an example embodiment, a method of fabricating a slurry solution may include forming a frame portion including silicon oxide (SiO₂), the frame portion having a spherical shape, forming a plurality of pores in the frame portion such that the plurality of pores are at least partially surrounded by the frame portion, and forming a plurality of first abrasive elements in the plurality of pores such that the plurality of first abrasive elements at least partially fill the plurality of pores, where the plurality of first abrasive elements include Ce(OH)₄.

According to an aspect of an example embodiment, a method of fabricating a semiconductor device may include loading a wafer on a polishing pad, providing a slurry solution including an abrasive on the polishing pad, polishing a surface of the wafer using the slurry solution, and unloading the wafer from the polishing pad, where the abrasive includes a first frame portion including an oxide and having a spherical shape, a plurality of pores at least partially surrounded by the first frame portion in the abrasive, and a plurality of first abrasive elements at least partially filling the plurality of pores, and where the plurality of first abrasive elements include Ce(OH)₄.

### BRIEF DESCRIPTION OF DRAWINGS

The above and other aspects, features, and advantages of certain example embodiments of the present disclosure will be more apparent from the following description taken in conjunction with the accompanying drawings, in which:

FIG. 1 is a diagram illustrating a wafer polishing apparatus that performs a chemical mechanical polishing (CMP) process using a slurry solution according to one or more example embodiments of the present disclosure;

FIG. 2 is a cross-sectional view illustrating an abrasive contained in a slurry solution according to one or more example embodiments of the present disclosure;

FIG. 3 is a flowchart illustrating a method for fabricating an abrasive contained in the slurry solution according to one or more example embodiments of the present disclosure;

FIG. 4 and FIG. 5 are cross-sectional views illustrating intermediate steps of a method for fabricating the abrasive contained in the slurry solution according to one or more example embodiments of the present disclosure;

FIG. 6 is a flowchart illustrating a method for fabricating a semiconductor device using the slurry solution according to one or more example embodiments of the present disclosure;

FIG. 7 is a cross-sectional view illustrating an abrasive contained in a slurry solution according to one or more example embodiments of the present disclosure;

FIG. 8 is a cross-sectional view illustrating an abrasive contained in a slurry solution according to one or more example embodiments of the present disclosure;

FIG. 9 is a cross-sectional view illustrating an abrasive contained in a slurry solution according to one or more example embodiments of the present disclosure;

FIG. 10 is a cross-sectional view illustrating an abrasive contained in a slurry solution according to one or more example embodiments of the present disclosure;

FIG. 11 is a flowchart illustrating a method for fabricating the abrasive contained in the slurry solution as shown in FIG. 10 according to one or more example embodiments; and

FIG. 12 is a cross-sectional view illustrating an intermediate step of the method for fabricating the abrasive contained in the slurry solution as shown in FIG. 10 according to one or more example embodiments.

### DETAILED DESCRIPTION

Hereinafter, example embodiments of the disclosure will be described in detail with reference to the accompanying drawings. The same reference numerals are used for the same components in the drawings, and redundant descriptions thereof will be omitted. The embodiments described herein are example embodiments, and thus, the disclosure is not limited thereto and may be realized in various other forms.

As used herein, expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

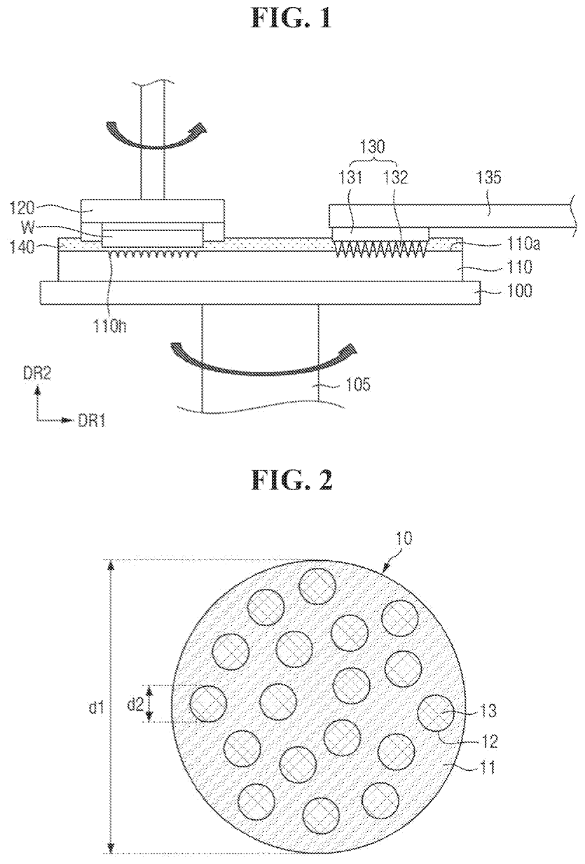

A wafer polishing apparatus that performs a chemical mechanical polishing (CMP) process using a slurry solution according to some embodiments of the present disclosure is described with reference to FIGS. 1 and 2.

FIG. 1 is a diagram illustrating a wafer polishing apparatus that performs a CMP process using a slurry solution according to one or more embodiments of the present disclosure. FIG. 2 is a cross-sectional view illustrating an abrasive contained in a slurry solution according to one or more example embodiments of the present disclosure.

Referring to FIG. 1 and FIG. 2, the wafer polishing apparatus that performs the CMP process using a slurry solution according to some embodiments of the present disclosure may include a stage 100, a support 105, a polishing pad 110, a polishing head 120, a disk 130, and disk connector 135.

The wafer polishing apparatus according to some embodiments of the present disclosure may be configured to perform a CMP process on a surface of a wafer W to polish the surface of the wafer W. For example, the wafer W may be a substrate including a semiconductor material or a non-semiconductor material. The wafer W may include one or more layers formed on the substrate.

The polishing pad 110 may be disposed on the stage 100. The stage 100 may support the polishing pad 110. The support 105 may be connected to the stage 100. For example, as shown in FIG. 1, the support 105 may rotate the stage 100. Thus, the polishing pad 110 disposed on the stage 100 may be rotated. The polishing pad 110 may have a disk shape, for example. The polishing pad 110 may include particles for polishing the surface of the wafer W. For example, the polishing pad 110 may include an elastic material such as polyurethane with a rough surface.

Hereinafter, a horizontal direction DR1 may be defined as a direction parallel to an upper surface 110a of the polishing pad 110. A vertical direction DR2 may be defined as a direction perpendicular to the upper surface 110a of the polishing pad 110. That is, the vertical direction DR2 may be defined as a direction perpendicular to the horizontal direction DR1.

The polishing head 120 may be disposed on the upper surface 110a of the polishing pad 110. The polishing head 120 may grip the wafer W. That is, the wafer W may be loaded onto the polishing head 120. The polishing head 120 may press the wafer W onto the upper surface 110a of the polishing pad 110 in the vertical direction DR2. The polishing head 120 may be rotated on top of the upper surface 110a of the polishing pad 110 while holding the wafer W. For example, the wafer W held by the polishing head 120 may be rotated while contacting the upper surface 110a of the polishing pad 110. The wafer W may be mechanically polished via sliding contact with the upper surface 110a of the polishing pad 110 under the presence of the slurry solution 140.

The disk 130 may be disposed on the upper surface 110a of the polishing pad 110. For example, disk 130 may be spaced apart from the polishing head 120 in the horizontal direction DR1. For example, the disk 130 may form a plurality of grooves 110h on the upper surface 110a of the polishing pad 110. The disk 130 may include a disk pad 131 and a plurality of contacts 132 protruding from a bottom of the disk pad 131. The disk pad 131 may be connected to the disk connector 135 and thus may be fixed onto the upper surface 110a of the polishing pad 110.

A bottom of each of the plurality of contacts 132 may contact the upper surface 110a of the polishing pad 110. For example, a lower distal end of each of the plurality of contacts 132 may be formed in a pointed shape. While the polishing pad 110 rotates, the lower distal end of each of the plurality of contacts 132 may form the plurality of grooves 110h on the upper surface 110a of the polishing pad 110. That is, the lower distal end of each of the plurality of contacts 132 may be disposed inside each of the plurality of grooves 110h. For example, each of the plurality of grooves 110h may be formed in a circular line shape on the upper surface 110a of the polishing pad 110.

The slurry solution 140 may be provided onto the upper surface 110a of the polishing pad 110. For example, the slurry solution 140 may also be present inside the plurality of grooves 110h formed on the upper surface 110a of the polishing pad 110. The slurry solution 140 may be used to chemically planarize the surface of the wafer W. For example, the wafer W may be chemically polished by the slurry solution 140 present inside the plurality of grooves 110h on the upper surface 110a of the polishing pad 110. The surface of the wafer W may be polished mechanically via respective rotations of the polishing pad 110 and the wafer W, and may be chemically polished by the slurry solution present inside the plurality of grooves 110h. For example, during the polishing process, a lower surface of the wafer W may be etched to have the same thickness.

For example, the slurry solution 140 may be a liquid containing chemicals and abrasives 10. For example, the abrasive 10 may have a shape of a sphere. However, the present disclosure is not limited thereto. In some embodiments, a cross-sectional shape of the abrasive 10 may be oval.

Referring to FIG. 2, for example, the abrasive 10 may include a frame portion 11, a plurality of pores 12, and abrasive elements 13. The frame portion 11 may serve as a base frame of the abrasive 10. For example, the frame portion 11 may have a spherical shape. However, the present disclosure is not limited thereto. In some embodiments, a cross-sectional shape of the frame portion 11 may be oval. The frame portion 11 may include an oxide. For example, the frame portion 11 may include silicon oxide (SiO₂). In some embodiments, the frame portion 11 may include cerium oxide (CeO₂), zirconium oxide (ZrO₂), or aluminum oxide (Al₂O₃).

The plurality of pores 12 may be formed inside the abrasive 10. For example, each of the plurality of pores 12 may be formed inside (e.g., within) the frame portion 11. For example, each of the plurality of pores 12 may be surrounded by the frame portion 11. For example, each of the plurality of pores 12 may have a spherical shape. However, the present disclosure is not limited thereto. In some embodiments, a cross-sectional shape of each of the plurality of pores 12 may be oval.

FIG. 2 shows that the plurality of pores 12 are spaced from each other. However, the present disclosure is not limited thereto. In some embodiments, some of the plurality of pores 12 may be connected to each other (i.e., some of the plurality of pores 12 may contact each other). Furthermore, FIG. 2 shows that the frame portion 11 surrounds all of the plurality of pores 12. However, the present disclosure is not limited thereto. In some embodiments, some of the plurality of pores 12 may be exposed through an outer peripheral surface of the frame portion 11.

A diameter d1 of the frame portion 11 may be larger than a diameter d2 of each of the plurality of pores 12. For example, the diameter d1 of the frame portion 11 may range from about 50 nm to about 200 nm. For example, the diameter d2 of each of the plurality of pores 12 may range from 1 nm to 50 nm.

The abrasive element 13 may fill at least a portion of each of the plurality of pores 12. That is, an abrasive element 13 may be included for each of the plurality of pores 12, such that each of the plurality of pores 12 is respectively and at least partially filled with a respective abrasive element 13. For example, the abrasive element 13 may entirely fill an interior of each of the plurality of pores 12. The abrasive element 13 may function as a component that chemically polishes the surface of the wafer W. The abrasive element 13 may be disposed inside (i.e., within) each of the plurality of pores 12 spaced apart from each other, such that a surface region of the abrasive element 13 may be increased. The abrasive element 13 may include a material different from that of the frame portion 11. For example, the abrasive element 13 may include Ce(OH)₄. In some further embodiments, the abrasive element 13 may include cerium oxide (CeO₂).

In the abrasive 10 contained in the slurry solution according to some embodiments of the present disclosure, the plurality of pores 12 may be formed inside (i.e., within) the frame portion 11, and the abrasive element 13 may fill each of the plurality of pores 12. As a result, the surface region of the abrasive element 13 contained in the abrasive 10 may increase, thereby increasing a polishing amount in the CMP process. In other words, the slurry solution according to some embodiments of the present disclosure may increase the productivity of the CMP process to reduce the cost of the CMP process.

A method for fabricating the abrasive contained in the slurry solution according to some embodiments of the present disclosure is described with reference to FIGS. 2 to 5.

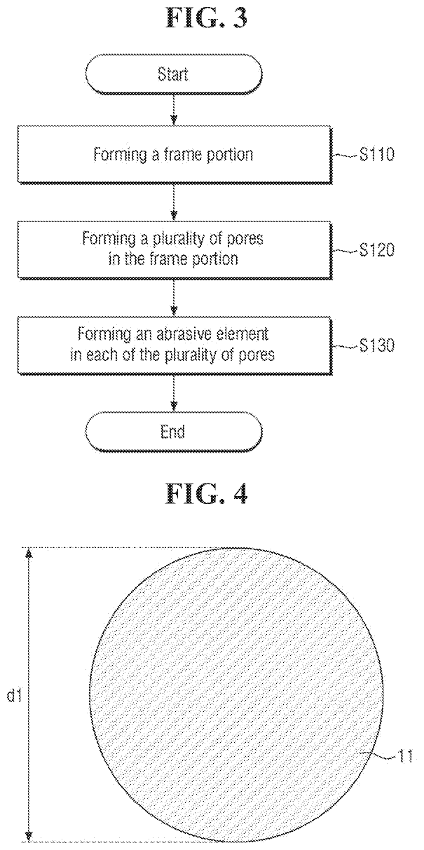

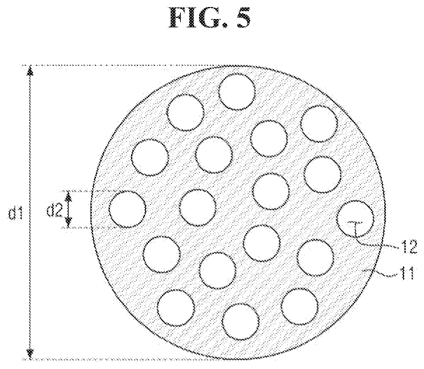

FIG. 3 is a flowchart illustrating a method for fabricating an abrasive contained in the slurry solution according to one or more example embodiments of the present disclosure. FIG. 4 and FIG. 5 are cross-sectional views illustrating intermediate steps of a method for fabricating the abrasive contained in the slurry solution according to one or more example embodiments of the present disclosure.

Referring to FIG. 3 and FIG. 4, the frame portion 11 may be formed in operation S110. For example, the frame portion 11 may have a spherical shape. The frame portion 11 may include the oxide. For example, the frame portion 11 may include silicon oxide (SiO₂). In some embodiments, the frame portion 11 may include cerium oxide (CeO₂), zirconium oxide (ZrO₂), or aluminum oxide (Al₂O₃). For example, the diameter d1 of the frame portion 11 may range from about 50 nm to about 200 nm.

Referring to FIG. 3 and FIG. 5, the plurality of pores 12 may be formed inside (i.e., within) the frame portion 11 in operation S120. For example, each of the plurality of pores 12 may be surrounded by the frame portion 11. For example, each of the plurality of pores 12 may have a spherical shape. For example, the diameter d2 of each of the plurality of pores 12 may range from about 1 nm to about 50 nm.

Referring to FIG. 3 and FIG. 2, the abrasive element 13 may be formed inside (i.e., within) each of the plurality of pores 12 in operation S130. For example, the abrasive element 13 may entirely fill the interior of each of the plurality of pores 12. For example, the abrasive element 13 may include Ce(OH)₄. In some embodiments, the abrasive element 13 may include cerium oxide (CeO₂). In this fabricating process, the abrasive 10 as shown in FIG. 2 may be fabricated.

A method for fabricating a semiconductor device using the slurry solution according to some embodiments of the present disclosure is described with reference to FIGS. 1, 2 and 6.

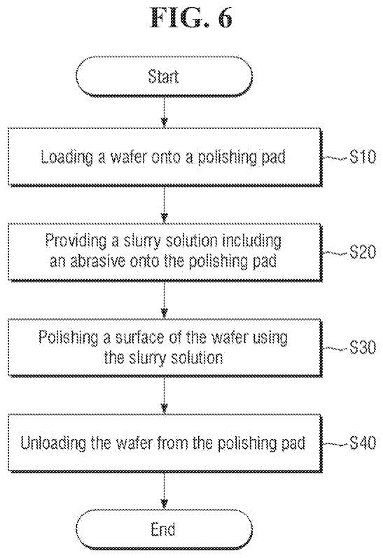

FIG. 6 is a flowchart illustrating a method for fabricating a semiconductor device using the slurry solution according to one or more example embodiments of the present disclosure.

Referring to FIG. 1, FIG. 2, and FIG. 6, the wafer W may be loaded on the upper surface 110a of the polishing pad 110 in operation S10. The wafer W may be held by the polishing head 120 at a lower portion thereof and may be loaded on the upper surface 110a of the polishing pad 110. The slurry solution 140 containing the abrasive 10 may be provided onto the upper surface 110a of the polishing pad 110 in operation S20. For example, the slurry solution 140 may be present inside the plurality of grooves 110h formed on the upper surface 110a of the polishing pad 110.

The surface of the wafer W may be polished using the slurry solution 140 in operation S30. For example, the surface of the wafer W may be polished by rotating the polishing pad 110 and the polishing head 120, respectively. For example, the surface of the wafer W may be chemically polished by the slurry solution 140 present inside the plurality of grooves 110h on the upper surface 110a of the polishing pad 110. The abrasive element 13 contained in the slurry solution 140 may function as a particle that chemically polishes the surface of the wafer W. Furthermore, the surface of the wafer W may be mechanically polished by respective rotations of the polishing pad 110 and the wafer W. After the polishing process on the wafer W has been completed, the wafer W may be unloaded from the polishing pad 110 in operation S40.

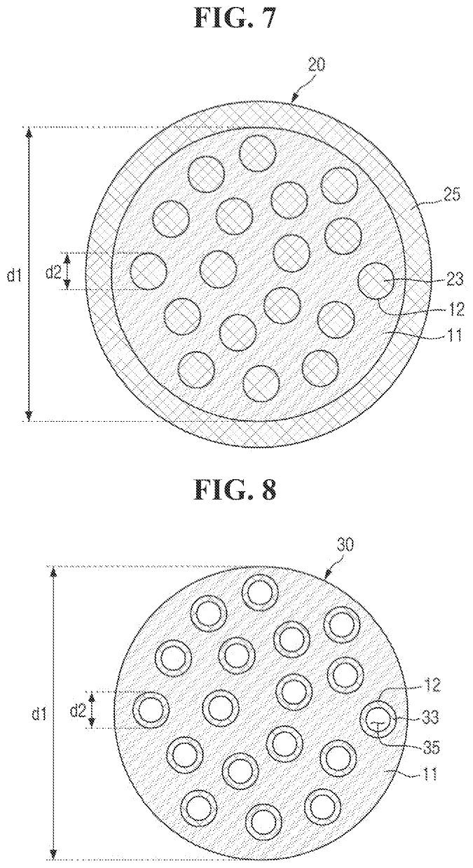

The abrasive contained in the slurry solution according to some embodiments of the present disclosure is described with reference to FIG. 7. The following description focuses on differences thereof from the abrasive as shown in FIG. 2.

FIG. 7 is a cross-sectional view illustrating an abrasive contained in a slurry solution according to one or more example embodiments of the present disclosure.

Referring to FIG. 7, in the abrasive 20 contained in the slurry solution according to some embodiments of the present disclosure, the abrasive 20 may include a plurality of first abrasive elements 23 and a second abrasive element 25 that surrounds an outer peripheral surface of the frame portion 11.

An abrasive 20 may include the frame portion 11, the plurality of pores 12, the plurality of first abrasive elements 23 and a second abrasive element 25. For example, the plurality of first abrasive elements 23 may be formed inside each of the plurality of pores 12 and the second abrasive element 25 may surround the outer peripheral surface of the frame portion 11. For example, the plurality of first abrasive elements 23 may entirely fill the inside of each of the plurality of pores 12. For example, the second abrasive element 25 may entirely surround the outer circumference of the frame portion 11. In the process where the plurality of first abrasive elements 23 fills each of the plurality of pores 12, the second abrasive element 25 may be formed on the outer circumferential surface of the frame portion 11. Thus, the abrasive 20 as shown in FIG. 7 may be fabricated.

The abrasive contained in the slurry solution according to some embodiments of the present disclosure is described with reference to FIG. 8. The following description focuses on differences thereof from the abrasive as shown in FIG. 2.

FIG. 8 is a cross-sectional view illustrating an abrasive contained in a slurry solution according to one or more example embodiments of the present disclosure.

Referring to FIG. 8, in the abrasive 30 contained in the slurry solution according to some embodiments of the present disclosure, an abrasive element 33 may be formed along and in a surface of each of the plurality of pores 12.

An abrasive 30 may include the frame portion 11, the plurality of pores 12, the plurality of abrasive elements 33, and an air gap 35. The abrasive element 33 may be partially formed inside each of the plurality of pores 12. For example, the abrasive element 33 may be formed along and in the surface of each of the plurality of pores 12. For example, the abrasive element 33 may be formed conformally. However, the present disclosure is not limited thereto.

The air gap 35 may be formed inside each of the plurality of pores 12. The air gap 35 may be surrounded by the abrasive element 33 inside each of the plurality of pores 12. That is, the air gap 35 may be defined by the abrasive element 33. In the process of filling the inside of each of the plurality of pores 12 with the abrasive element 33, the abrasive element 33 may be formed along and in the surface of each of the plurality of pores 12, such that the abrasive 30 as shown in FIG. 8 may be fabricated.

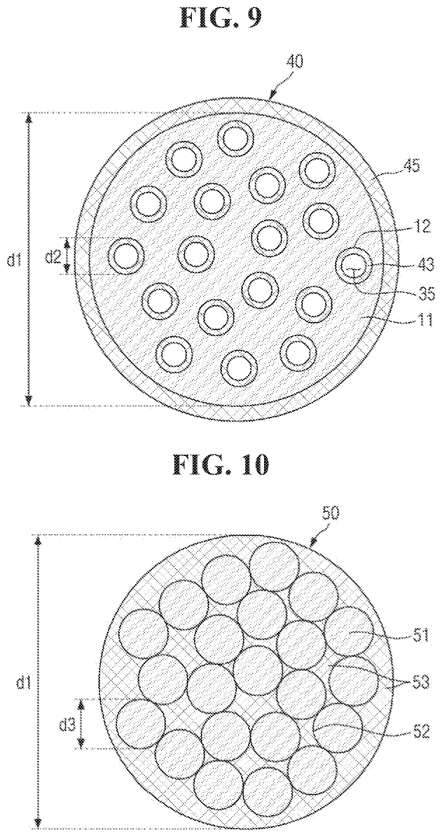

The abrasive contained in the slurry solution according to some embodiments of the present disclosure is described with reference to FIG. 9. The following description focuses on differences thereof from the abrasive as shown in FIG. 2.

FIG. 9 is a cross-sectional view illustrating an abrasive contained in a slurry solution according to one or more example embodiments of the present disclosure.

Referring to FIG. 9, in the abrasive 40 contained in the slurry solution according to some embodiments of the present disclosure, a plurality of first abrasive elements 43 may be formed along and in the surface of each of the plurality of pores 12. Furthermore, a second abrasive element 45 may surround the outer circumference of the frame portion 11.

An abrasive 40 may include the frame portion 11, the plurality of pores 12, the plurality of first abrasive elements 43, the corresponding air gaps 35 and a second abrasive element 45. The plurality of first abrasive elements 43 may be partially formed inside each of the plurality of pores 12. For example, the plurality of first abrasive elements 43 may be formed along and in the surface of each of the plurality of pores 12. For example, the plurality of first abrasive elements 43 may be formed conformally. However, the present disclosure is not limited thereto. Furthermore, the second abrasive element 45 may be formed on the outer peripheral surface of the frame portion 11. For example, the second abrasive element 45 may entirely surround the outer circumference of the frame portion 11.

The air gap 35 may be formed inside each of the plurality of pores 12. The air gap 35 may be surrounded by the abrasive element 43 inside each of the plurality of pores 12. That is, the air gap 35 may be defined by the abrasive element 43. In the process of filling the inside of each of the plurality of pores 12 with the plurality of first abrasive elements 43, the plurality of first abrasive elements 43 may be formed in and along the surface of each of the plurality of pores 12 and the second abrasive element 45 may surround the outer circumference of the frame portion 11. Thus, the abrasive 40 as shown in FIG. 9 may be fabricated.

The abrasive contained in the slurry solution according to some embodiments of the present disclosure is described with reference to FIG. 10. The following description focuses on differences thereof from the abrasive as shown in FIG. 2.

FIG. 10 is a cross-sectional view illustrating an abrasive contained in a slurry solution according to one or more example embodiments of the present disclosure.

Referring to FIG. 10, the abrasive 50 contained in the slurry solution according to some embodiments of the present disclosure may include a plurality of frame portions 51.

An abrasive 50 may include the plurality of frame portions 51, a plurality of pores 52, and abrasive elements 53. The abrasive elements 53 may be referred to as a plurality of abrasive elements 53 provided around the plurality of frame portions 51 and in the pores 52 defined by the spaces between the plurality of frame portions 51 For example, the plurality of frame portions 51 may contact each other. Each of the plurality of frame portions 51 may act as a base frame of the abrasive 50.

For example, each of the plurality of frame portions 51 may have a spherical shape. However, the present disclosure is not limited thereto. In some further embodiments, a cross-sectional shape of each of the plurality of frame portions 51 may be elliptical. Each of the plurality of frame portions 51 may include oxide. For example, each of the plurality of frame portions 51 may include silicon oxide (SiO₂). In some embodiments, each of the plurality of frame portions 51 may include cerium oxide (_{CeO2}), zirconium oxide (ZrO₂), or aluminum oxide (Al₂O₃).

The diameter d1 of the abrasive 50 may be larger than a diameter d3 of each of the plurality of frame portions 51. For example, the diameter d1 of the abrasive 50 may range from about 50 nm to about 200 nm. For example, the diameter d3 of each of the plurality of frame portions 51 may range from about 3 nm to about 50 nm.

Each of the plurality of pores 52 may be formed inside the abrasive 50. For example, each of the plurality of pores 52 may be formed between adjacent ones of the plurality of frame portions 51. For example, each of the plurality of pores 52 may be surrounded by the plurality of frame portions 51. In other words, each of the plurality of pores 52 may be defined as a region between adjacent ones of the plurality of frame portions 51.

The abrasive element 53 may entirely fill the inside of each of the plurality of pores 52. Furthermore, the abrasive element 53 may surround each of the plurality of frame portions 51. FIG. 10 shows that the abrasive element 53 surrounds each of the plurality of frame portions 51. However, the present disclosure is not limited thereto. In some embodiments, surfaces of some of the plurality of frame portions 51 may be exposed. The abrasive element 53 may include a material different from that of each of the plurality of frame portions 51. For example, the abrasive element 53 may include Ce(OH)₄. In some embodiments, the abrasive element 53 may include cerium oxide (CeO₂).

A method for fabricating the abrasive contained in the slurry solution as shown in FIG. 10 is described with reference to FIGS. 10 to 12.

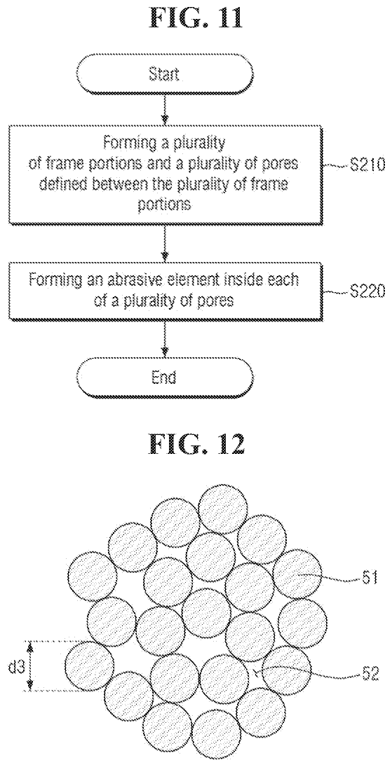

FIG. 11 is a flowchart illustrating a method for fabricating the abrasive contained in the slurry solution as shown in FIG. 10 according to one or more example embodiments. FIG. 12 is a cross-sectional view illustrating an intermediate step of the method for fabricating the abrasive contained in the slurry solution as shown in FIG. 10 according to one or more example embodiments.

Referring to FIG. 11 and FIG. 12, the plurality of frame portions 51 and the plurality of pores 52 may be formed in operation S210. For example, the plurality of frame portions 51 may contact each other. For example, each of the plurality of frame portions 51 may have a spherical shape. For example, each of the plurality of frame portions 51 may include silicon oxide (SiO₂). In some embodiments, each of the plurality of frame portions 51 may include cerium oxide (CeO₂), zirconium oxide (ZrO₂), or aluminum oxide (Al₂O₃). For example, the diameter d3 of each of the plurality of frame portions 51 may range from about 3 nm to about 50 nm.

Each of the plurality of pores 52 may be formed between adjacent ones of the plurality of frame portions 51. Each of the plurality of pores 52 may be defined as a region between adjacent ones of the plurality of frame portions 51. In other words, each of the plurality of pores 52 may be defined as a region surrounded with the adjacent ones of the plurality of frame portions 51.

Referring to FIG. 11 and FIG. 10, the abrasive element 53 may be formed inside each of the plurality of pores 52 in operation S220. For example, the abrasive element 53 may entirely fill the interior of each of the plurality of pores 52. Furthermore, the abrasive element 53 may surround each of the plurality of frame portions 51. For example, the abrasive element 53 may include Ce(OH)₄. In some embodiments, the abrasive element 53 may include cerium oxide (CeO₂). In this fabricating process, the abrasive 50 as shown in FIG. 10 may be fabricated.

Each of the embodiments provided in the above description is not excluded from being associated with one or more features of another example or another embodiment also provided herein or not provided herein but consistent with the disclosure

While the disclosure has been particularly shown and described with reference to embodiments thereof, it will be understood that various changes in form and details may be made therein without departing from the spirit and scope of the following claims.

What is claimed is:

1. A slurry solution comprising:
an abrasive comprising:
a first frame portion comprising an oxide and having a spherical shape;
a plurality of pores in the abrasive; and
a plurality of first abrasive elements at least partially filling the plurality of pores,
wherein the plurality of first abrasive elements comprise Ce(OH)₄.

2. The slurry solution of claim 1, wherein the first frame portion comprises silicon oxide (SiO₂).

3. The slurry solution of claim 1, wherein each of the plurality of pores is within the first frame portion.

4. The slurry solution of claim 3, wherein a diameter of the first frame portion is in a range from about 50 nm to about 200 nm.

5. The slurry solution of claim 3, wherein a diameter of each of the plurality of pores is in a range from about 1 nm to about 50 nm.

6. The slurry solution of claim 1, wherein at least one of the plurality of first abrasive elements entirely fills in at least one of the plurality of pores. “in” is missing.

7. The slurry solution of claim 1, wherein the plurality of first abrasive elements are conformally provided along a surface of the plurality of pores.

8. The slurry solution of claim 7, wherein the abrasive further comprises a plurality of air gaps respectively surrounded by the plurality of first abrasive elements in the plurality of pores.

9. The slurry solution of claim 1, further comprising a second abrasive element at least partially surrounding an outer circumferential surface of the first frame portion.

10. The slurry solution of claim 1, further comprising a plurality of frame portions contacting each other, the plurality of frame portions comprising the first frame portion,
wherein each of the plurality of frame portions comprises an oxide, and
wherein each of the plurality of pores is between adjacent frame portions of the plurality of frame portions.

11. The slurry solution of claim 10, wherein a diameter of each of the plurality of frame portions is in a range from about 3 nm to about 50 nm.

12. A method of fabricating a slurry solution, the method comprising:
forming a frame portion comprising silicon oxide (SiO₂), the frame portion having a spherical shape;
forming a plurality of pores in the frame portion such that the plurality of pores are at least partially surrounded by the frame portion; and
forming a plurality of first abrasive elements respectively in the plurality of pores such that the plurality of first abrasive elements at least partially fill the plurality of pores,
wherein the plurality of first abrasive elements comprise Ce(OH)₄.

13. The method of claim 12, wherein the plurality of first abrasive elements entirely fills in the plurality of pores.

14. The method of claim 12, wherein the forming the plurality of first abrasive elements in the plurality of pores comprises conformally forming the plurality of first abrasive elements along a surface of the plurality of pores.

15. The method of claim 12, further comprising forming a second abrasive element at least partially surrounding an outer peripheral surface of the frame portion.

16. A method of fabricating a semiconductor device, the method comprising:
loading a wafer on a polishing pad;
providing a slurry solution comprising an abrasive on the polishing pad;
polishing a surface of the wafer using the slurry solution; and
unloading the wafer from the polishing pad,
wherein the abrasive comprises:
a first frame portion comprising an oxide and having a spherical shape;
a plurality of pores at least partially surrounded by the first frame portion in the abrasive; and
a plurality of first abrasive elements at least partially filling the plurality of pores, and
wherein the plurality of first abrasive elements comprise Ce(OH)₄.

17. The method of claim 16, wherein each of the plurality of pores is formed inside the first frame portion.

18. The method of claim 16, wherein at least one of the plurality of first abrasive elements entirely fills in at least one of the plurality of pores.

19. The method of claim 16, wherein the plurality of first abrasive elements are conformally provided along a surface of each of the plurality of pores.

20. The method of claim 16, further comprising a second abrasive element at least partially surrounding an outer circumferential surface of the first frame portion.
